(19) United States
(12) Patent Application Publication
(10) Pub. No.: US 2024/0222490 A1
(43) Pub. Date: Jul. 4, 2024

(54) SEMICONDUCTOR DEVICE AND MANUFACTURING METHOD

(71) Applicant: GUANGDONG ZHINENG TECHNOLOGIES, CO. LTD., Guangzhou (CN)

(72) Inventors: Zilan LI, Guangzhou (CN); Lezhi WANG, Guangzhou (CN)

(21) Appl. No.: 18/400,480

(22) Filed: Dec. 29, 2023

(30) Foreign Application Priority Data
Dec. 29, 2022 (CN) 202211717910.2

(51) Int. Cl. H01L 29/778; H01L 29/417; H01L 29/66

(52) U.S. Cl. CPC H01L 29/7788; H01L 29/41775; H01L 29/66462

(57) ABSTRACT

The present invention relates to a semiconductor device, including: a first channel layer; a second channel layer; a first barrier layer, where a vertical first two-dimensional carrier gas is included at the position in the first channel layer close to an interface between the first channel layer and the first barrier layer; a second barrier layer, where a vertical second two-dimensional carrier gas is included at the position in the second channel layer close to an interface between the second channel layer and the second barrier layer, and the first channel layer and the second channel layer are located between the first barrier layer and the second barrier layer; a source electrode electrically connected to the first two-dimensional carrier gas and the second two-dimensional carrier gas; a drain electrode electrically connected to the first two-dimensional carrier gas and the second two-dimensional carrier gas; and a gate electrode located between the source electrode and the drain electrode, where the first channel layer and the second channel layer are doped such that the first two-dimensional carrier gas between the first channel layer and the gate electrode and the second two-dimensional carrier gas between the second channel layer and the gate electrode are depleted. The present application further relates to a manufacturing method for a semiconductor device.

### BACKGROUND

### Technical Field

The present invention relates to the field of semiconductors, and in particular, to a semiconductor device.

### Description of the Related Art

There are still some defects in the existing normally close semiconductors of vertical structures.

### BRIEF SUMMARY

For the technical problems existing in the prior art, the present invention provides a semiconductor device, including: a first channel layer; a second channel layer; a first barrier layer, where a vertical first two-dimensional carrier gas is included at the position in the first channel layer close to an interface between the first channel layer and the first barrier layer; a second barrier layer, where a vertical second two-dimensional carrier gas is included at the position in the second channel layer close to an interface between the second channel layer and the second barrier layer, and the first channel layer and the second channel layer are located between the first barrier layer and the second barrier layer; a source electrode electrically connected to the first two-dimensional carrier gas and the second two-dimensional carrier gas; a drain electrode electrically connected to the first two-dimensional carrier gas and the second two-dimensional carrier gas; and a gate electrode located between the source electrode and the drain electrode, where the first channel layer and the second channel layer are doped such that the first two-dimensional carrier gas between the first channel layer and the gate electrode and the second two-dimensional carrier gas between the second channel layer and the gate electrode are depleted.

Particularly, one or more of the source electrode, the drain electrode and the gate electrode includes discrete electrode portions.

Particularly, the semiconductor device further includes: a substrate including a first vertical interface and a second vertical interface; and a first buffer layer and a second buffer layer respectively located between the first vertical interface and the first channel layer and between the second vertical interface and the second channel layer.

Particularly, no substrate is included, or most of the substrate is removed.

Particularly, the drain electrode extends below the first channel layer and the second channel layer.

Particularly, a first buffer layer is included below the first channel layer, a second buffer layer is included below the first channel layer, and the drain electrode extends below the first buffer layer and the second buffer layer, where the first buffer layer and the second buffer layer are doped.

Particularly, the first channel layer and the second channel layer include one or more doped first portions, of which the doping types are opposite to the doping types of the first two-dimensional carrier gas and the second two-dimensional carrier gas, and the doping concentration is such that the first two-dimensional carrier gas and the second two-dimensional carrier gas of the one or more first portions are depleted in the absence of an applied voltage.

Particularly, the first channel layer and the second channel layer include one or more doped second portions in contact with the source electrode, and the doping types of the one or more doped second portions are identical to the carrier types of the first two-dimensional carrier gas and the second two-dimensional carrier gas.

Particularly, the first channel layer and the second channel layer include one or more doped third portions in contact with the drain electrode, and the doping types of the one or more doped third portions are identical to the carrier types of the first two-dimensional carrier gas and the second two-dimensional carrier gas.

Particularly, the first channel layer and the second channel layer include one or more doped third portions in contact with the doped first buffer layer and the second buffer layer, and the doping types of the one or more third portions are identical to the doping types of the first buffer layer and the second buffer layer as well as the carrier types of the first two-dimensional carrier gas and the second two-dimensional carrier gas.

Particularly, the first channel layer and the second channel layer include one or more doped fourth portions located between the one or more first portions and the drain electrode and close to the one or more first portions or in contact with the one or more first portions, the doping types of the one or more fourth portions are opposite to the doping types of the first two-dimensional carrier gas and the second two-dimensional carrier gas, and the doping concentration of the one or more fourth portions is such that the first two-dimensional carrier gas and the second two-dimensional carrier gas of the one or more fourth portions are not depleted in the absence of an applied voltage.

The present invention further relates to a manufacturing method for a semiconductor device, including: providing a first channel layer and a second channel layer; providing a first barrier layer and a second barrier layer, where a vertical first two-dimensional carrier gas is included at the position in the first channel layer close to an interface between the first channel layer and the first barrier layer, and a vertical second two-dimensional carrier gas is included at the position in the second channel layer close to an interface between the second channel layer and the second barrier layer, where the first channel layer and the second channel layer are located between the first barrier layer and the second barrier layer; and providing a source electrode, a drain electrode and a gate electrode, where the source electrode is electrically connected to the first two-dimensional carrier gas and the second two-dimensional carrier gas, the drain electrode is electrically connected to the first two-dimensional carrier gas and the second two-dimensional carrier gas, and the gate electrode is located between the source electrode and the drain electrode, where the first channel layer and the second channel layer are doped such that the first two-dimensional carrier gas between the first channel layer and the gate electrode and the second two-dimensional carrier gas between the second channel layer and the gate electrode are depleted.

Particularly, the method further includes: respectively forming a first buffer layer and a second buffer layer outside the first vertical interface and the second vertical interface.

Particularly, the method further includes: cladding the first buffer layer and the second buffer layer; exposing upper surfaces of the first buffer layer and the second buffer layer; and beginning to form the first channel layer and the second channel layer on the upper surfaces of the first buffer layer and the second buffer layer.

Particularly, the method further includes: freely and epitaxially growing the first channel layer and the second channel layer in an unconstrained mode.

Particularly, the method further includes: forming a shared hole; and forming the first channel layer and the second channel layer in the shared hole in a constrained mode.

Particularly, the method further includes: respectively forming a first hole and a second hole; and forming the first channel layer and the second channel layer in the first hole and the second hole in a constrained mode.

Particularly, the providing a first channel layer and a second channel layer further includes: providing one or more doped first portions, of which the doping types are opposite to the doping types of the first two-dimensional carrier gas and the second two-dimensional carrier gas, and the doping concentration is such that the first two-dimensional carrier gas and the second two-dimensional carrier gas of the one or more first portions are depleted in the absence of an applied voltage.

Particularly, the providing a first channel layer and a second channel layer further includes: providing one or more doped second portions in contact with the source electrode, where the doping types of the one or more doped second portions are identical to the carrier types of the first two-dimensional carrier gas and the second two-dimensional carrier gas.

Particularly, the providing a first channel layer and a second channel layer further includes: providing one or more doped third portions in contact with the drain electrode, where the doping types of the one or more doped third portions are identical to the carrier types of the first two-dimensional carrier gas and the second two-dimensional carrier gas.

Particularly, the providing a first channel layer and a second channel layer further includes: providing one or more doped third portions in contact with the doped first buffer layer and the second buffer layer, where the doping types of the one or more third portions are identical to the doping types of the first buffer layer and the second buffer layer as well as the carrier types of the first two-dimensional carrier gas and the second two-dimensional carrier gas.

Particularly, the providing a first channel layer and a second channel layer further includes: providing one or more doped fourth portions located between the one or more first portions and the drain electrode and close to the one or more first portions or in contact with the one or more first portions, where the doping types of the one or more fourth portions are opposite to the doping types of the first two-dimensional carrier gas and the second two-dimensional carrier gas, and the doping concentration of the one or more fourth portions is such that the first two-dimensional carrier gas and the second two-dimensional carrier gas of the one or more fourth portions are not depleted in the absence of an applied voltage.

Particularly, the method further includes: flipping and supporting the substrate on a temporary substrate; removing the substrate or most of the substrate; removing the first buffer layer and the second buffer layer, and exposing the first channel layer and the second channel layer; and forming the drain electrode on the first channel layer and the second channel layer.

Particularly, the method further includes: flipping and supporting the substrate on the temporary substrate; removing the substrate or most of the substrate, and exposing the first buffer layer and the second buffer layer; and forming the drain electrode on the first buffer layer and the second buffer layer, where the first buffer layer and the second buffer layer are doped.

Particularly, the method further includes: carrying out electrical interconnection with the source electrode and the gate electrode above the first channel layer and the second channel layer; and carrying out electrical interconnection with the drain electrode below the first channel layer and the second channel layer.

### BRIEF DESCRIPTION OF THE SEVERAL VIEWS OF THE DRAWINGS

Preferred embodiments of the present invention are further described below in detail with reference to the accompanying drawings.

FIG. 1A is a schematic structural diagram of a semiconductor device according to an embodiment of the present invention.

FIG. 1B is a schematic structural diagram of a semiconductor device according to an embodiment of the present invention.

FIG. 1C is a schematic structural diagram of a semiconductor device according to an embodiment of the present invention.

FIGS. 2A to 2P are flow diagrams of a manufacturing method for a semiconductor device according to an embodiment of the present invention.

FIGS. 3A and 3B are flow diagrams of a manufacturing method for a semiconductor device according to an embodiment of the present invention.

### DETAILED DESCRIPTION

To make the objectives, technical solutions, and advantages of the embodiments of the present invention clearer, the following clearly and completely describes the technical solutions in the embodiments of the present invention with reference to the accompanying drawings in the embodiments of the present invention. Apparently, the described embodiments are merely some rather than all the embodiments of the present invention. All other embodiments obtained by a person of ordinary skill in the art based on the embodiments of the present invention shall fall within the protection scope of the present invention.

In the detailed description below, reference can be made to individual drawings of the description that are part of the present application to illustrate the specific embodiments of the present application. In the drawings, similar reference numerals describe substantially similar components in different figures. Each specific embodiment of the present application is described in sufficient detail below, so that a person of ordinary skill with relevant knowledge and technology in the art can implement the technical solution of the present application. It should be understood that other embodiments or structural, logical or electrical changes of embodiments of the present application may also be used.

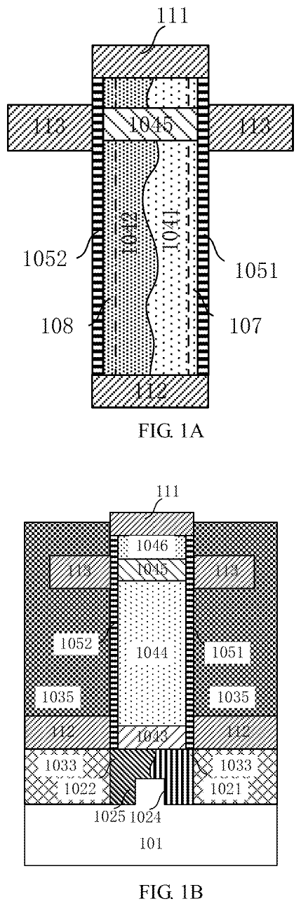

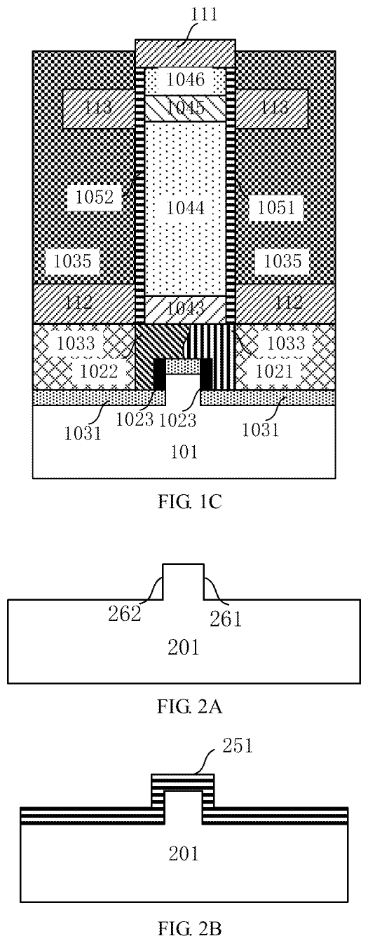

The present application provides a semiconductor device. FIG. 1A is a structural diagram of a semiconductor device according to an embodiment of the present invention. As shown in the figure, the semiconductor device includes:
a first channel layer 1041 and a second channel layer 1042; a first barrier layer 1051 provided outside the first channel layer 1041, where a vertical first two-dimensional carrier gas 107 is included at the position in the first channel layer 1041 close to an interface between the first channel layer 1041 and the first barrier layer 1051; a second barrier layer 1052 provided outside the second channel layer 1042, where a vertical second two-dimensional carrier gas 108 is included at the position in the second channel layer 1042 close to an interface between the second channel layer 1042 and the second barrier layer 1052, where the first channel layer 1041 and the second channel layer 1042 are located between the first barrier layer 1051 and the second barrier layer 1052, and in some embodiments, the first channel layer 1041 and the second channel layer 1042 are merged in the middle through crystal growth to form an interface between the first channel layer 1041 and the second channel layer 1042;
a source electrode 111 electrically connected to the first two-dimensional carrier gas 107 and the second two-dimensional carrier gas 108;
a drain electrode 112 electrically connected to the first two-dimensional carrier gas 107 and the second two-dimensional carrier gas 108; and
a gate electrode 113 located between the source electrode 111 and the drain electrode 112, where the first channel layer 1041 and the second channel layer 1042 are doped such that the first two-dimensional carrier gas 107 between the first channel layer 1041 and the gate electrode and the second two-dimensional carrier gas 108 between the second channel layer 1042 and the gate electrode are depleted. In some embodiments, the first two-dimensional carrier gas 107 and the second two-dimensional carrier gas 108 are 2DEG. In some embodiments, a doping region 1045 is strong P-type doping. Because the first two-dimensional carrier gas 107 and the second two-dimensional carrier gas 108 are 2DEG, the carriers thereof are electrons, and the electrons in the doping region 1045 are holes, under normal conditions, the holes in the doping region 1045 may deplete the electrons of the first two-dimensional carrier gas 107 and the second two-dimensional carrier gas 108 in this region, such that a conductive path between the source electrode and the drain electrode is turned off. When the bias is applied to the gate electrode, a large number of electrons enter the doping region 1045, the electrons in the first two-dimensional carrier gas 107 and the second two-dimensional carrier gas 108 are no longer depleted, and a conductive channel between the source electrode and the drain electrode is re-formed.

In some embodiments, one or more of the source electrode, the drain electrode and the gate electrode includes discrete electrode portions. For example, there are two source electrodes and two drain electrodes in FIG. 1A, which are electrically connected to the first two-dimensional carrier gas 107 and the second two-dimensional carrier gas 108, respectively.

In the structure as shown in FIG. 1A, a traditional substrate structure is not included, which is removed in the manufacturing process. In some embodiments, the substrate may also be retained.

FIG. 1B is a schematic structural diagram of a semiconductor device according to an embodiment of the present invention. The substrate 101 includes a boss structure that includes two vertical interfaces 1024 and 1025. The lattice of the vertical interface 1024 has hexagonal symmetry. The structure further includes a first buffer layer 1021 and a second buffer layer 1022 respectively located between the first vertical interface 1024 and the first channel layer and between the second vertical interface 1025 and the second channel layer (for clarity, the representations of the first channel layer, the second channel layer, the first two-dimensional carrier gas 107 and the second two-dimensional carrier gas 108 are omitted from the figure).

In some embodiments, the substrate 101 may be removed, or most of the substrate 101 may be removed (for example, only the boss structure is remained). In some embodiments, the drain electrode extends below the first buffer layer and the second buffer layer.

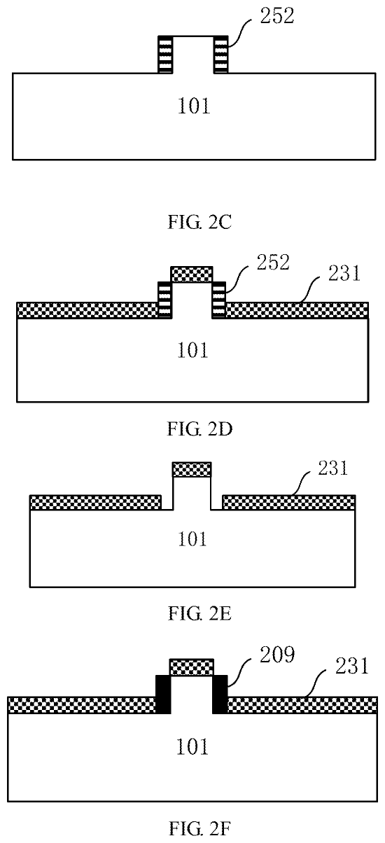

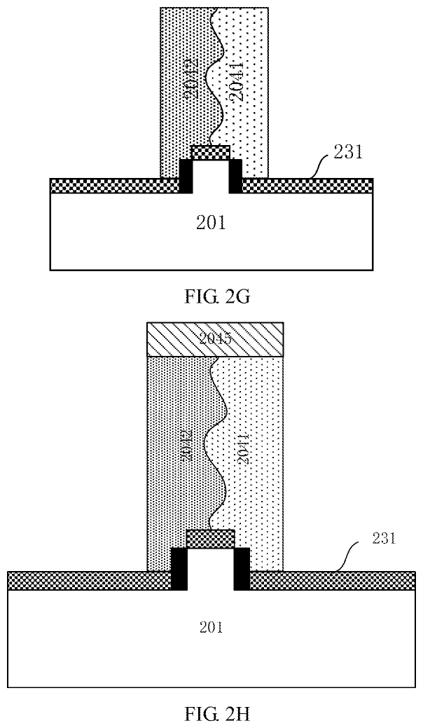

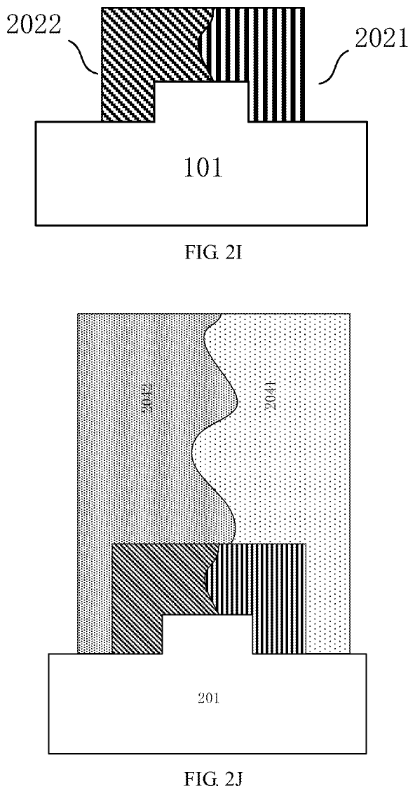

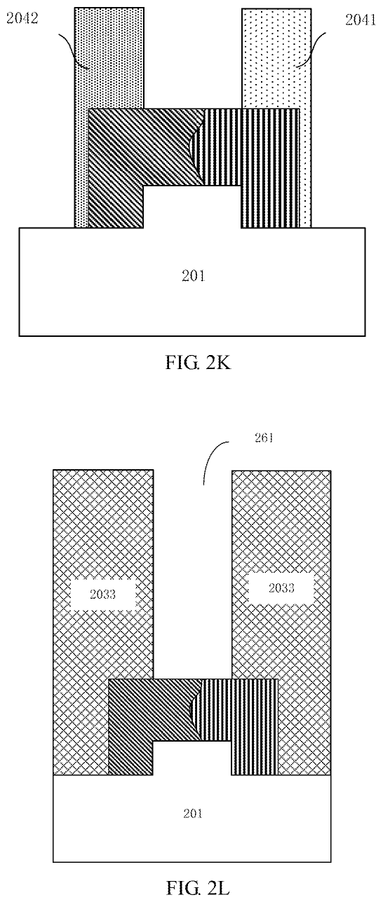

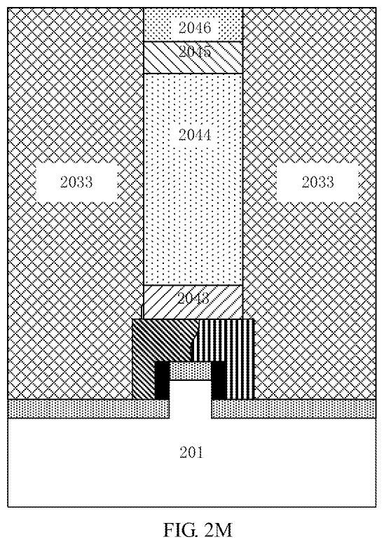

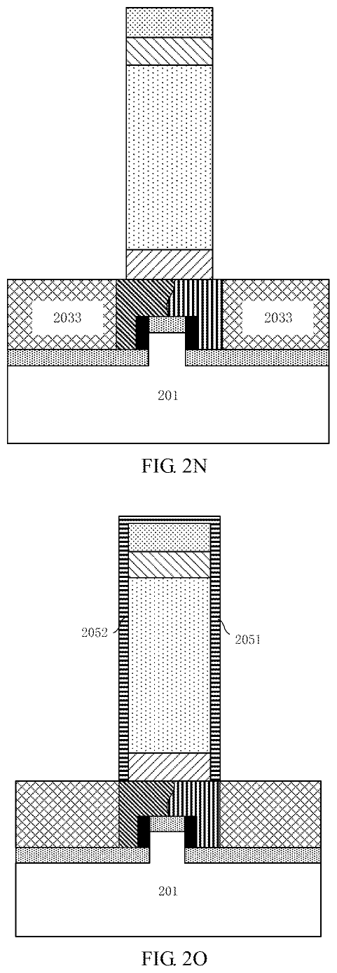

In the structure as shown in FIG. 2B, the channel layer may include a variety of doping structures.

There is no substrate in the traditional sense in the structure because the substrate is removed in the device preparation process. This allows the electrodes to be formed below the device, which not only facilitates the process flow, but also creates good heat dissipation and improves the device performance. As shown in some embodiments of the present invention, a Schottky diode including 2DEG or 2DHG formed in the vertical direction has many excellent properties. First, the voltage resistance of the Schottky diode is greatly improved. Even a Si substrate with lower cost and more mature process, the voltage resistance of the Schottky diode is also close to that of a Schottky diode on an intrinsic GaN substrate. Secondly, the contact area between such a vertical channel device and the substrate is relatively small, and the influence of the substrate is relatively small, which is relatively easy to overcome the problems of epitaxial layer cracking of traditional planar devices. Furthermore, by increasing the thickness of the vertical channel, the conductive area of the device may be increased, and the area of the substrate can be used more fully.

According to one embodiment of the present invention, the material of the substrate 101 may be Si, SiC, intrinsic GaN or sapphire Al₂O₃, etc. In some embodiments, the Si substrate with lower cost and more mature process than other materials is selected as an example to illustrate the technical solution of the present invention. A person skilled in the art should understand that the piezoelectric material of the present invention is not limited thereto.

In some embodiments, the buffer layers 1021 and 1022 may be one or more of AlN, GaN, AlGaN, InGaN, AlInN, and AlGaInN. According to one embodiment of the present invention, the materials of the channel layers 1041 and 1042 may be GaN. According to one embodiment of the present invention, the materials of the barrier layers 1051 and 1052 may be AlGaN. A person skilled in the art should understand that a back barrier layer, the channel layer and a channel provision layer of the present invention are not limited thereto, and it is sufficient to meet the requirements of a band gap between the back barrier layer, the channel layer and the channel provision layer to form a corresponding 2DEG or 2DHG.

In some embodiments, the buffer layers 1021 and 1022 form a vertical interface 161 and a vertical interface 162 from the substrate 101. The buffer layers 1021 and 1022 may grow outwards and upwards respectively, and are merged in the middle to form a fin-like structure. The first channel layer 1041 and the second channel layer 1042 may further grow at the buffer layers 1021 and 1022, respectively, and form a structure similar to that shown in FIG. 1B. In some embodiments, if a (0001) surface is formed at the barrier layer and the channel layer, a two-dimensional carrier gas in the channel layer is 2DEG, and if a (000-1) surface is formed at the barrier layer and the channel layer, the two-dimensional carrier gas in the channel layer is 2DHG. In some embodiments, the first two-dimensional carrier gas 107 and the second two-dimensional carrier gas 108 are both 2DEG or 2DHG. In some embodiments, the first two-dimensional carrier gas 107 and the second two-dimensional carrier gas 108 are two two-dimensional carrier gases of different carrier types.

In some embodiments, there is no obvious interface between the first channel layer and the second channel layer. In some embodiments, the Schottky diode further includes a separating layer configured to separate the first channel layer from the second channel layer.

In some embodiments, the first channel layer and the second channel layer include one or more doped first portions 1045, of which the doping types are opposite to the carrier types of the first two-dimensional carrier gas and the second two-dimensional carrier gas, and the doping concentration is such that the first two-dimensional carrier gas and the second two-dimensional carrier gas of the one or more first portions 1045 are depleted in the absence of an applied voltage. The first portions allows the device to remain normally off without applying a bias.

In some embodiments, the first channel layer and the second channel layer include one or more doped second portions 1046 in contact with the source electrode 111, and the doping types of the one or more doped second portions 1046 are identical to the carrier types of the first two-dimensional carrier gas and the second two-dimensional carrier gas. The second portion 1046 may reduce device resistance.

In some embodiments, the first channel layer and the second channel layer include one or more doped third portions 1043 in contact with the drain electrode 112, and the doping types of the one or more doped third portions 1043 are identical to the carrier types of the first two-dimensional carrier gas and the second two-dimensional carrier gas.

In some embodiments, the first channel layer and the second channel layer include one or more doped third portions 1043 in contact with the doped first buffer layer 1021 and the second buffer layer 1022, and the doping types of the one or more third portions 1043 are identical to the doping types of the first buffer layer 1021 and the second buffer layer 1022 as well as the carrier types of the first two-dimensional carrier gas and the second two-dimensional carrier gas. The third portion can reduce the contact resistance of the drain electrode 112.

In some embodiments, the first channel layer and the second channel layer include one or more doped fourth portions 1044 located between the one or more first portions 1045 and the drain electrode 112 and close to the one or more first portions 1045 or in contact with the one or more first portions 1045, the doping types of the one or more fourth portions 1044 are opposite to the carrier types of the first two-dimensional carrier gas and the second two-dimensional carrier gas, and the doping concentration of the one or more fourth portions 1044 is such that the first two-dimensional carrier gas and the second two-dimensional carrier gas of the one or more fourth portions 1044 are not depleted in the absence of an applied voltage. The fourth portion 1044 may effectively modulate the electric field distribution and reduce the local excessive electric field.

FIG. 1C is a schematic structural diagram of a semiconductor device according to an embodiment of the present invention.

The substrate 101 includes a boss structure that has two vertical interfaces. A nucleating layer 103 is provided on each vertical interface. In some embodiments, the Si substrate with lower cost and more mature process than other materials is selected. Si in the substrate may have a melt-back effect with GaN in the channel layer 105, which affects the growth of the channel layer 105. Therefore, the nucleating layer 103 is introduced, the material of which may be AlN, covering the vertical interface 102 of the Si substrate 101 to avoid direct contact between Si in the Si substrate 101 and GaN in the channel layer 105. When the substrate is made of a non-Si material, the nucleating layer 103 is not necessary. Therefore, the nucleating layer 103 is an alternative structure for the Schottky diode. A buffer layer 1021 and a buffer layer 1022 are provided outside the nucleating layer 103.

In some embodiments, an insulating layer 1031 is formed on the substrate 101. The insulating layer 1033 is provided on both sides of the buffer layer. In some embodiments, a support layer 1035 is provided outside the barrier layer, and the support layer 1035 may further improve the device mechanical strength.

In some embodiments, the channel layers are doped, where the first channel layer and the second channel layer (in order to display that other structures are no longer distinguished) include one or more doped first portions 1046. In some embodiments, the first portion 1046 is in contact with the first electrode 111, and the doping type is identical to the carrier types of the first two-dimensional carrier gas and the second two-dimensional carrier gas.

In some embodiments, the first channel layer and the second channel layer include one or more doped second portions 1044 close to the source electrode 112, and the doping types of the one or more doped second portions 1044 are identical to the carrier types of the first two-dimensional carrier gas and the second two-dimensional carrier gas.

In some embodiments, the first channel layer and the second channel layer include one or more doped second portions 1044 in contact with the doped first buffer layer and the second buffer layer. Moreover, the doping types of the one or more second portions 1044 are identical to the doping types of the first buffer layer and the second buffer layer as well as the carrier types of the first two-dimensional carrier gas and the second two-dimensional carrier gas.

The first portion and the second portion are identical to the carrier types of the first two-dimensional carrier gas and the second two-dimensional carrier gas, which can reduce the device resistance and the contact resistance of the electrodes.

In some embodiments, the first channel layer and the second channel layer epitaxially grow through the limitation of a shared hole. That is, a vertical hole is formed, and then corresponding structures of the first channel layer and the second channel layer are grown in the hole. In some embodiments, the first channel layer epitaxially grows through the limitation of the first hole, and the second channel layer epitaxially grows through the limitation of a second hole.

A manufacturing method for the semiconductor device of this embodiment includes the following steps. In step 21, vertical interfaces 261 and 262 are formed on a substrate 201, as shown in FIG. 2A. Hence, a boss is formed on the substrate 201, and the vertical interfaces 261 and 262 are located on two sides of the boss, respectively. In this embodiment, a device manufactured on a Si substrate is taken as an example. As understood by a person skilled in the art, other substrates such as intrinsic GaN, Al₂O₃(sapphire), and SiC may also achieve similar structures.

In step 22, a protective layer is formed on the substrate 201, as shown in FIG. 2B. The protective layer covers the substrate 201. In some embodiments, SiN may be grown using techniques such as LPCVD, and a protective layer 251 is formed on the entire substrate 201. A person skilled in the art should understand that other methods for forming a protective layer may also be applied here.

In step 23, the protective layer on the substrate is partially removed, to expose an upper surface of the substrate, as shown in FIG. 2C. In some embodiments, the protective layer on the substrate is removed by an etching technique with vertical orientation, to expose the upper surface of the substrate, leaving a protective layer 252 of the vertical interface.

In step 24, an insulating layer is grown on the substrate, to cover a vertical interface of the exposed substrate, as shown in FIG. 2D. In some embodiments, SiO2 is grown on the substrate 201 using techniques such as substrate oxidation to form an insulating layer 231. The insulating layer 231 covers the upper surface of the exposed substrate.

In step 25, the protective layer is removed, as shown in FIG. 2E. In some embodiments, SiN on the side wall is removed by selective etching technique, so that the vertical interface of the substrate 201 is exposed, but the insulating layer 231 on the substrate 201 is retained at the same time.

A person skilled in the art should understand that there are still other techniques to form an insulating layer on the substrate, but expose the vertical interface of the substrate at the same time.

Furthermore, in step 26, a nucleating layer is formed on the exposed vertical surface of the substrate, as shown in FIG. 2F.

For the Si substrate, due to the melt-back effect of Ga atoms, a nucleating layer 209 is adopted. As known by a person skilled in the art, GaN may be nucleated and grown directly on Al₂O₃ (sapphire), SiC, or intrinsic GaN; however, it is difficult to control the crystal quality. Therefore, the nucleating layer 209 may be introduced in the general process. In some cases, it is not necessary to include step 207 to introduce the nucleating layer 209 such as low-temperature GaN or AlN.

The growth ability of an AlN selective region is weak, so there may be certain growth on the separating layer, which has a negative effect on the semiconductor device. In some embodiments, a wafer may be removed after the growth of AlN, and only an AlN nucleating layer on the vertical plane is retained, and the AlN in other places may be removed through anisotropic etching, for example, dry etching using vertical downward ion bombardment. Since AlN on the vertical surface is weakly bombarded with ions and AlN on other surfaces is strongly bombarded, the goal of retaining only the AlN on the vertical plane is achieved.

In step 27, as shown in FIG. 2G, a channel layer is formed on the nucleating layer. Channel layers 2041 and 2042 are formed on the nucleating layer 209 through epitaxial growth. In step 28, a channel provision layer is formed on the channel layer, as shown in FIG. 2H. Barrier layers 2051 and 2052 are formed on the channel layers 2041 and 2042 through epitaxial growth. A vertical first two-dimensional carrier gas is included at the position in the first channel layer close to an interface between the first channel layer and the first barrier layer, and a vertical second two-dimensional carrier gas is included at the position in the second channel layer close to an interface between the second channel layer and the second barrier layer. The first channel layer and the second channel layer are located between the first barrier layer and the second barrier layer.

Channels are generated at an interface of nitride semiconductors having narrow band gaps/nitride semiconductors having wide band gaps, and are located in the channel layer having a low band gap and close to the interface of the channel layer/the channel provision layer. The most common example is a GaN/AlGaN interface. The channels may accommodate two-dimensional electron gases or two-dimensional hole gases. Carriers (electrons or holes) flow mainly within the channels and have high mobility and charge density.

In step 28, as shown in FIG. 2I, a first electrode and a second electrode are formed. Channel layers 2041 and 2042 are formed on the nucleating layer 209 through epitaxial growth. In step 28, a channel provision layer is formed on the channel layer, as shown in FIG. 2H. Channel provision layers 2051 and 2052 are formed on the channel layers 2041 and 2042 through epitaxial growth.

In some embodiments, the method further includes: step 29: respectively forming a first buffer layer and a second buffer layer outside the first vertical interface and the second vertical interface of the substrate, as shown in FIG. 2J. The structure as shown in FIG. 2J does not include the nucleating layer and the insulating layer in the foregoing structure. In some embodiments, the substrate 201 may be a heterogeneous substrate.

In some embodiments, the method further includes: cladding the first buffer layer and the second buffer layer; exposing upper surfaces of the first buffer layer and the second buffer layer; and beginning to form the first channel layer and the second channel layer on the upper surfaces of the first buffer layer and the second buffer layer. As shown in FIG. 2K and FIG. 2L, the first buffer layer and the second buffer layer may further epitaxially grow the first channel layer 2041 and the second channel layer 2042. In some embodiments, the method further includes: freely and epitaxially growing the first channel layer and the second channel layer in an unconstrained mode, and then selecting a portion to be retained through an etching technique. As shown in FIG. 2K, the first channel layer 2041 and the second channel layer 2042 may be gradually merged in the middle. In the structure as shown in FIG. 2L, a gap is formed between the first channel layer 2041 and the second channel layer 2042, and a separating layer may be provided in the gap to separate the first channel layer 2041 and the second channel layer 2042.

In some embodiments, the method further includes: forming a shared hole; and forming the first channel layer and the second channel layer in the shared hole in a constrained mode, as shown in FIG. 2M. The structure as shown in FIG. 2M may be formed by depositing on the etched insulating layer, and includes insulating layers 2033 and a hole 261 between the two insulating layers 2033. In the hole 261, the upper surfaces of the first buffer layer and the second buffer layer are exposed, and the corresponding structures may be selectively grown based on the first buffer layer and the second buffer layer. For example, in FIG. 2N, the first channel layer 2041 and the second channel layer 2042 are grown, respectively.

In some embodiments, the method further includes: respectively forming a first hole and a second hole; and forming the first channel layer and the second channel layer in the first hole and the second hole in a constrained mode. In some embodiments, two hole structures may be formed by etching the insulating layer, the upper surfaces of the first buffer layer and the second buffer layer are respectively exposed in the two hole structures, and then the first channel layer and the second channel layer are formed in the first hole and the second hole in a constrained mode.

In some embodiments, the method further includes: providing one or more doped first portions 2045, of which the doping types are opposite to the carrier types of the first two-dimensional carrier gas and the second two-dimensional carrier gas, and the doping concentration is such that the first two-dimensional carrier gas and the second two-dimensional carrier gas of the one or more first portions 2045 are depleted in the absence of an applied voltage.

In some embodiments, the method further includes: providing one or more doped second portions 2046 in contact with the source electrode, where the doping types of the one or more doped second portions 2046 are identical to the carrier types of the first two-dimensional carrier gas and the second two-dimensional carrier gas.

In some embodiments, the method further includes: providing one or more doped third portions 2043 in contact with the drain electrode, where the doping types of the one or more doped third portions 2043 are identical to the carrier types of the first two-dimensional carrier gas and the second two-dimensional carrier gas.

In some embodiments, the method further includes: providing one or more doped third portions 2043 in contact with the doped first buffer layer and the second buffer layer, where the doping types of the one or more third portions are identical to the doping types of the first buffer layer and the second buffer layer as well as the carrier types of the first two-dimensional carrier gas and the second two-dimensional carrier gas.

In some embodiments, the method further includes: providing one or more doped fourth portions 2044 located between the one or more first portions and the drain electrode and close to the one or more first portions 2045 or in contact with the one or more first portions 2045, the doping types of the one or more fourth portions 2044 are opposite to the carrier types of the first two-dimensional carrier gas and the second two-dimensional carrier gas, and the doping concentration of the one or more fourth portions 2044 is such that the first two-dimensional carrier gas and the second two-dimensional carrier gas of the one or more fourth portions 2044 are not depleted in the absence of an applied voltage.

In some embodiments, the method further includes: etching an insulating layer, as shown in FIG. 2N. The insulating layer 2033 is etched to expose the first and second channel layers. Then, barrier layers, electrodes and other structures may be gradually formed.

In some embodiments, the method further includes: carrying out electrical interconnection with the source electrode and the gate electrode above the first channel layer and the second channel layer; and carrying out electrical interconnection with the drain electrode below the first channel layer and the second channel layer. In some embodiments, the method further includes: forming at least two source electrodes and drain electrodes on two discrete sides of the barrier layer, where electrical interconnection with the source electrode and the gate electrode is carried out above the first channel layer and the second channel layer, and electrical interconnection with the drain electrode is carried out below the first channel layer and the second channel layer.

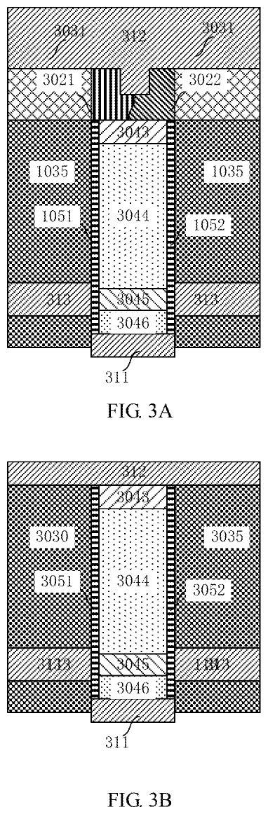

FIGS. 3A and 3B are flow diagrams of a manufacturing method for a semiconductor device according to an embodiment of the present invention.

Referring to FIG. 1B and FIG. 1C, as shown in FIG. 3A and FIG. 3B, the method includes: flipping and supporting the substrate on a temporary substrate; removing the substrate or most of the substrate; removing the first buffer layer and the second buffer layer, and exposing the first channel layer and the second channel layer; and forming the drain electrode 312 on the first channel layer and the second channel layer. Alternatively, the method includes: flipping and supporting the substrate on the temporary substrate; removing the substrate or most of the substrate, and exposing the first buffer layer and the second buffer layer; and forming the drain electrode on the first buffer layer and the second buffer layer. In some embodiments, the first buffer layer and the second buffer layer are doped.

The above embodiments are only for illustrative purposes of the present invention, and are not limitations on the present invention, and a person of ordinary skill in the art can also make various changes and variants without departing from the scope of the present invention. Therefore, all equivalent technical solutions should also belong to the scope of disclosure of the present invention.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor device, comprising:
a first channel layer;
a second channel layer;
a first barrier layer, wherein a vertical first two-dimensional carrier gas is comprised at the position in the first channel layer close to an interface between the first channel layer and the first barrier layer;
a second barrier layer, wherein a vertical second two-dimensional carrier gas is comprised at the position in the second channel layer close to an interface between the second channel layer and the second barrier layer, and the first channel layer and the second channel layer are located between the first barrier layer and the second barrier layer;
a source electrode electrically connected to the first two-dimensional carrier gas and the second two-dimensional carrier gas;
a drain electrode electrically connected to the first two-dimensional carrier gas and the second two-dimensional carrier gas; and
a gate electrode located between the source electrode and the drain electrode;
wherein the first channel layer and the second channel layer are doped such that the first two-dimensional carrier gas between the first channel layer and the gate electrode and the second two-dimensional carrier gas between the second channel layer and the gate electrode are depleted.

2. The semiconductor device according to claim 1, wherein one or more of the source electrode, the drain electrode and the gate electrode comprise discrete electrode portions.

3. The semiconductor device according to claim 1, further comprising: a substrate comprising a first vertical interface and a second vertical interface; and a first buffer layer and a second buffer layer respectively located between the first vertical interface and the first channel layer and between the second vertical interface and the second channel layer.

4. The semiconductor device according to claim 1, wherein no substrate is comprised, or most of the substrate is removed.

5. The semiconductor device according to claim 4, wherein the drain electrode extends below the first channel layer and the second channel layer.

6. The semiconductor device according to claim 4, wherein a first buffer layer is comprised below the first channel layer, a second buffer layer is comprised below the second channel layer, and the drain electrode extends below the first buffer layer and the second buffer layer, wherein the first buffer layer and the second buffer layer are doped.

7. The semiconductor device according to claim 1, wherein the first channel layer and the second channel layer comprise one or more doped first portions, of which the doping types are opposite to the doping types of the first two-dimensional carrier gas and the second two-dimensional carrier gas, and the doping concentration is such that the first two-dimensional carrier gas and the second two-dimensional carrier gas of the one or more first portions are depleted in the absence of an applied voltage.

8. The semiconductor device according to claim 7, wherein the first channel layer and the second channel layer comprise one or more doped second portions in contact with the source electrode, and the doping types of the one or more doped second portions are identical to the carrier types of the first two-dimensional carrier gas and the second two-dimensional carrier gas.

9. The semiconductor device according to claim 7, wherein the first channel layer and the second channel layer comprise one or more doped third portions in contact with the drain electrode, and the doping types of the one or more doped third portions are identical to the carrier types of the first two-dimensional carrier gas and the second two-dimensional carrier gas.

10. The semiconductor device according to claim 7, wherein the first channel layer and the second channel layer comprise one or more doped third portions in contact with the doped first buffer layer and the second buffer layer, and the doping types of the one or more third portions are identical to the doping types of the first buffer layer and the second buffer layer as well as the carrier types of the first two-dimensional carrier gas and the second two-dimensional carrier gas.

11. The semiconductor device according to claim 7, wherein the first channel layer and the second channel layer comprise one or more doped fourth portions located between the one or more first portions and the drain electrode and close to the one or more first portions or in contact with the one or more first portions, the doping types of the one or more fourth portions are opposite to the doping types of the first two-dimensional carrier gas and the second two-dimensional carrier gas, and the doping concentration of the one or more fourth portions is such that the first two-dimensional carrier gas and the second two-dimensional carrier gas of the one or more fourth portions are not depleted in the absence of an applied voltage.
